(19) United States
(12) Patent Application Publication
(10) Pub. No.: US 2011/0180394 A1
(43) Pub. Date: Jul. 28, 2011

(54) SPUTTERING METHOD AND SPUTTERING APPARATUS

(76) Inventors: Tatsunori Isobe, Chiba (JP); Takashi Komatsu, Chiba (JP); Shigemitsu Satou, Kanagawa (JP); Hiroki Oozora, Kanagawa (JP); Hideo Taniguchi, Osaka (JP); Masao Kawaguchi, Osaka (JP)

(21) Appl. No.: 12/673,256

(22) PCT Filed: Aug. 18, 2008
(86) PCT No.: PCT/JP2008/064710

§ 371 Date: Feb. 12, 2010

(30) Foreign Application Priority Data
Aug. 20, 2007 (JP) 2007-213973

(51) Int. Cl. C23C 14/34

(52) U.S. Cl. 204/192.29; 204/298.08

(57) ABSTRACT

There is provided a sputtering method in which abnormal discharging due to charge-up of a to-be-processed substrate is restrained and in which a good transparent conductive film can be formed on a to-be-processed large-area substrate. Out of a plurality of targets disposed side by side with, and at a predetermined distance from, one another so as to lie opposite to the to-be-processed substrate inside a sputtering chamber, electric power is applied, by alternately changing polarity at a predetermined frequency, to the targets that form respective pairs. Each target is thus alternately switched to anode electrode and cathode electrode. Glow discharge is thus generated between the anode electrode and the cathode electrode to thereby form plasma atmosphere, whereby each target is sputtered. During sputtering, electric power application to each of the targets is intermittently stopped.

### TECHNICAL FIELD

The present invention relates to a sputtering method and a sputtering apparatus for forming a predetermined transparent conductive film on a surface of a substrate to be processed (also referred to as “to-be-processed substrate”), and relates in particular to the ones in which AC power sources are used.

### BACKGROUND ART

In a step of manufacturing a flat panel display (FPD), there is a sputtering method as one of the methods of forming a transparent conductive film of ITO, IZO and the like on a surface of a substrate such as glass and the like. In the sputtering method, ions in plasma atmosphere are accelerated toward, and impinged on, a target that is manufactured into a predetermined shape depending on the composition of the transparent conductive film to be formed on the surface of the substrate, and sputtered particles (target atoms) are caused to be splashed, and are adhered to, and deposited on, the surface of the to-be-processed substrate, whereby a predetermined transparent conductive film is formed.

As a result of recent increase in area of the FPD, it is known in Patent Document 1 to constitute the sputtering apparatus in the following manner. In other words, the sputtering apparatus described in the Patent Document 1 has: a plurality of the same shape of targets which are disposed side by side with one another inside a vacuum chamber so as to lie opposite to the to-be-processed substrate; and AC power sources which apply AC voltage, in a predetermined frequency by alternatively changing polarity, to the targets that respectively form pairs. Then, a predetermined sputtering gas (together with a reactant gas depending on the target species) is introduced in a vacuum. Targets that make pairs are supplied with power through the AC power sources. Each of the targets is alternately switched between anode electrode and cathode electrode. Glow discharge is thus caused to be generated between the anode electrode and the cathode electrode to thereby form a plasma atmosphere, whereby each of the targets is sputtered.

### Patent Document 1; JP-A-2005-290550

### DISCLOSURE OF THE INVENTION

### Problems to be Solved by the Invention

According to the above-described art, electric charges in charge-up held in retention at the surface of the targets will be cancelled during sputtering when the voltage of opposite phase is applied. Therefore, even in case oxide targets of indium and tin are used as the targets, the occurrence of abnormal discharging (arc discharge) attributable to the charge-up in the oxide targets can be restrained, so that a transparent conductive film can be formed well. On the other hand, the to-be-processed substrate that is insulated or floating in terms of electric potential inside the sputtering chamber will also be subject to charge-up. The electric charges in charge-up at the surface of the to-be-processed substrate will ordinarily be neutralized by, e.g., sputtering particles or ionized sputtering gas ions, and will therefore disappear.

However, in order to enhance a sputtering rate, in case the power supply to the targets is increased or the magnetic field strength on the surface of the targets is increased to thereby increase the plasma density near the surface of the targets, the amount of electric charges in charge-up at the surface of the to-be-processed substrate per unit time will increase, whereby charge-up becomes easier to be retained at the surface of the to-be-processed substrate. In particular, in case a transparent conductive film is formed on the surface of the to-be-processed substrate on which has been formed a metal film to constitute an electrode or an insulating film in the FPD manufacturing process, the electric charges in charge-up will become easier to retain on the insulating film on the surface of the to-be-processed substrate.

Should the electric charges in charge-up get retained on the to-be-processed substrate (or on the insulating film formed on the surface of the to-be-processed substrate), there are cases where the electric charges in charge-up will instantly jump over to the mask plate due to the difference in potential, e.g., at a position adjacent to the to-be-processed substrate and the grounded mask plate disposed in the periphery of the to-be-processed substrate, thereby resulting in an abnormal discharging (arc discharging) due to the above. Once the abnormal discharging takes place, problem arises in that the film on the surface of the to-be-processed substrate will suffer from damages, resulting in an unacceptable product, or in the occurrence of particles, and the like. The formation of good transparent conductive film will therefore be impeded.

Therefore, in view of the above problems, a first object of this invention is to provide a sputtering method in which the occurrence of abnormal discharging attributable to charge-up of the to-be-processed substrate is restrained and in which forming of good transparent conductive film on a large-area to-be-processed substrate is possible. In addition, a second object of this invention is to provide a sputtering apparatus in which the occurrence of abnormal discharging attributable to charge-up of the to-be-processed substrate is restrained and in which forming of good transparent conductive film on a large-area to-be-processed substrate is possible with a simplified arrangement.

### MEANS FOR SOLVING THE PROBLEMS

In order to solve the above-described problems, the sputtering method according to claim 1 of this invention is a sputtering method of forming a predetermined transparent conductive film on a surface of a substrate to be processed. The method comprises: introducing a process gas into a sputtering chamber; applying electric power to respective pairs of targets by alternately changing polarity at a predetermined frequency, the pairs of targets being formed out of a plurality of targets disposed side by side with, and at a predetermined distance to, one another in a manner to lie opposite to the to-be-processed substrate inside the sputtering chamber; alternately switching each of the targets to an anode electrode and a cathode electrode to generate glow discharge between the anode electrode and the cathode electrode such that a plasma atmosphere is formed to sputter each of the targets. During sputtering, application of electric power to each of the targets is intermittently stopped.

According to this invention, even if, during sputtering, the electrons ionized in front of the targets or the secondary electrons generated by sputtering will move toward the surface of the to-be-processed substrate to thereby cause the electric charges in charge-up to remain therein, electric application to each of the targets is intermittently stopped. Therefore, as a combined effect in that, in a state in which the electric application to each of the targets is stopped, the amounts of ionized electrons and secondary electrons moving toward the to-be-processed substrate are reduced, and that the electric charges in charge-up at the to-be-processed substrate (or an insulating film formed on the surface of the to-be-processed substrate) will disappear as a result of neutralization by the sputtered particles or ionized sputtering gas ions, the retention of the electric charges in charge-up at the surface of the to-be-processed substrate can be remarkably restricted. As a result, even in case where, in the FPD manufacturing step, a transparent conductive film is formed on a to-be-processed substrate on which a metal film to constitute electrode or an insulating film has been formed, the occurrence of abnormal discharging can be restrained and the transparent conductive film can be formed well. Therefore, the yield of the products in manufacturing FPDs can be improved.

If the intermittent stopping is performed at a constant cycle with respect to all of the targets disposed side by side with one another, the plasma in front of each of the targets is caused, during sputtering, to periodically disappear. As a consequence, in a state in which the plasma has disappeared, there will be no ionized electrons or secondary electrons that move toward the to-be-processed substrate. Therefore, the retention of the electric charges in charge-up at the surface of the to-be-processed substrate can further be reduced, and thus the abnormal discharging can surely be prevented from occurring.

Preferably, the sum of the time of intermittent stopping is set to a range below 10% of a sputtering time required to form a predetermined transparent conductive film in a constant thickness on the surface of the to-be-processed substrate. If the time of stopping the application of electric power to the targets is set longer, it may accordingly be possible to restrain the retention of the electric charges in charge-up at the surface of the to-be-processed substrate. However, if the time exceeds 10% of the sputtering time, the sputtering time for forming a transparent conductive film will become longer, thereby resulting in poor productivity.

As the targets, there are used oxide targets of indium and tin or alloy targets of indium and tin, and the process gas to be introduced into the processing chamber includes an H₂O gas. Then at the time of intermittent stopping of applying electric power to each of the targets, the H₂O gas (reactant gas) introduced into the processing chamber is supplied to the entire surface of the to-be-processed substrate without being locally consumed. As a result, the transparent conductive film is prevented from being locally micro-crystallized, whereby an amorphous transparent conductive film can be obtained in a more stable manner.

Further, in order to solve the above-described problems, the sputtering apparatus according to claim 5 of this invention comprises: a plurality of oxide targets of indium and tin or alloy targets of indium and tin, the targets being disposed in a sputtering chamber side by side with, and at a predetermined distance to, one another in a manner to lie opposite to a to-be-processed substrate; AC power sources enabling to apply electric power to the targets that respectively make a pair, by alternately changing polarity at a predetermined frequency; and a gas introducing means enabling to introduce a process gas into the sputtering chamber. Each of the AC power sources has: a switching element for switching between application and stopping of electric power to respective pairs of targets; and a control means for controlling the switching of the switching element such that the power application to the targets is intermittently stopped during sputtering.

### EFFECT OF THE INVENTION

As described hereinabove, according to the sputtering method and the sputtering apparatus of this invention, in case a transparent conductive film is formed in sputtering by using AC power sources on a large-area to-be-processed substrate, the occurrence of abnormal discharging attributable to the charge-up at the to-be-processed substrate can be restricted. There can thus be attained an effect in that the formation of a good transparent conductive film becomes possible.

### BEST MODE OF CARRYING OUT THE INVENTION

With reference to FIGS. 1 and 2, reference numeral 1 denotes a magnetron sputtering (hereinafter referred to as “sputtering”) apparatus according to an embodiment of this invention to form a transparent conductive film on the surface of a large-area substrate to be processed. The sputtering apparatus 1 is of an in-line type, has a vacuum chamber 11 which can be maintained at a predetermined vacuum pressure (e.g., 10⁻⁵ Pa) through an evacuating means (not illustrated) such as a rotary pump, a turbo molecular pump and the like, and constitutes a sputtering chamber (processing chamber) 12. A substrate transporting means 2 is disposed on an upper portion of the vacuum chamber 11. This substrate transporting means 2 is of a known construction and has a carrier 21 which supports the to-be-processed substrate S in a floating state in terms of electric potential. By intermittently driving a driving means (not illustrated), the substrate transporting means 2 sequentially transports the to-be-processed substrate S to a position lying opposite to targets which are to be described hereinafter.

In the sputtering chamber 12, there is mounted between the substrate transporting means 2 and the targets a grounded mask plate 13 in which is formed an opening 13a to which the to-be-processed substrate S faces. The mask plate 13 is disposed in order to prevent the sputtered particles from getting adhered to the surface of the carrier 21 and the like when a transparent conductive film is formed on the to-be-processed substrate S that has been transported to the position lying opposite to the targets. The vacuum chamber 11 has also a gas introducing means 3 for introducing a process gas into the sputtering chamber 12. The gas introducing means 3 has gas pipes 31 one end of each is mounted to a side wall, e.g., of the vacuum chamber 11. The other ends of the gas pipes 31 are communicated with gas sources 33 through a mass flow controller 32, respectively. The process gas includes a sputtering gas composed of a rare gas such as Ar and the like, and a reactant gas such as O₂, N₂, H₂O and the like which is appropriately selected depending on the composition of the transparent conductive film to be formed on the surface of the to-be-processed substrate S when the transparent conductive film is formed by reactive sputtering. Further, on the lower side of the vacuum chamber 11 there is disposed a cathode electrode C.

In order to enable to efficiently form a transparent conductive film on a large-area to-be-processed substrate S, the cathode electrode C has a plurality of targets (eight in this embodiment) 41a to 41h which are disposed at an equal distance to one another in a manner to lie opposite to the to-be-processed substrate S. Each of the targets 41a to 41h is appropriately manufactured, in a known method, of an oxide target of indium and tin or an alloy target of indium and tin, and the like, depending on the composition of the transparent conductive film such as an ITO, IZO and the like to be formed on the surface of the to-be-processed substrate S. Each of the targets is made into the same shape of, e.g., substantially rectangular parallelepiped (rectangle as seen in a top view). Each of the targets 41a to 41h is bonded, through a bonding material such as indium, tin and the like, to a backing plate 42 which cools the targets 41a to 41h during sputtering. Each of the targets 41a to 41h is mounted on a frame (not illustrated) of the cathode electrode C through an insulating material such that the sputtering surface 411 before use is positioned on an identical plane that is in parallel with the to-be-processed substrate S. In the circumference of the targets 41a to 41h that are disposed side by side with one another, there is disposed a grounded shield 43.

In addition, the cathode electrode C has magnet assemblies 5 in a position behind the respective targets 41a to 41h (i.e., on the side away from the sputtering surface 411). Each of the magnet assemblies 5 of the same construction has a supporting plate (yoke) 51 which is disposed in parallel with each of the targets 41a to 41h. When the targets 41a to 41h are rectangle as seen in front view, the supporting plates 51 are constructed by rectangular flat plates that are formed smaller in lateral width than each of the targets 41a to 41h in a manner to extend beyond both longitudinal sides of the targets 41a to 41h, and are made of a magnetic material which amplifies the attraction force of the magnet. On each of the supporting plates 51, there are disposed: a central magnet 52 which is disposed linearly in the center thereof to lie along the longitudinal direction thereof; and a peripheral magnet 53 which is disposed along the outer periphery of the supporting plate 51 so as to enclose the periphery of the central magnet 52, by changing the polarity on the side of the sputtering surface 411.

The volume of the central magnet 52 as converted to equivalent magnetization is designed to be equal to the sum of the volume of, e.g., the peripheral magnets 53 as converted to equivalent magnetization (peripheral magnet: central magnet: peripheral magnet=1:2:1). In front of the sputtering surface 411 of each of the targets 41a to 41h, there will be respectively formed a tunnel-shaped, well-balanced closed loop magnetic flux. According to this arrangement, by capturing electrons ionized on the front (sputtering surface 411) side of each of the targets 41a to 41h and secondary electrons generated by sputtering, the electron density in front of each of the targets 41a to 41h is enhanced, and the sputtering rate can thus be increased. Each of the magnet assemblies 5 is respectively coupled to a driving shaft D1 of the driving means D made up of a motor, an air cylinder and the like so as to be integral and be movable back and forth at an equal velocity between the two positions in a direction in which the targets 41a to 41h are disposed side by side with one another. As a result, since the region in which the sputtering rate becomes high can be varied, there can be obtained an eroded region uniformly over the entire surface of each of the targets 41a to 41h.

Each of the targets 41a to 41h is arranged to make pairs of targets (41a and 41b, 41c and 41d, 41e and 41f, 41g and 41h) by the adjoining two targets. AC power supplies E1 to E4 are allocated to respective pairs of targets. Output cables 75a, 75b from AC power supplies E1 to E4 are respectively connected to the pair of targets 41a, 41b (41c and 41d, 41e and 41f, 41g and 41h) (see FIG. 2). According to this arrangement, by means of the AC power supplies E1 to E4, AC voltage can be applied to respective pairs of targets 41a to 41h by alternately changing the polarity.

AC power supplies E1 to E4 are of the same construction and are made up of; a power supply portion 6 which enables the power supply; and an oscillating portion 7 which outputs the alternating voltage to the pairs of targets (41a and 41b, 41c and 41d, 41e and 41f, 41g and 41h) by alternately changing the polarity at a predetermined frequency. The wave form of the output voltage to each of the targets 41a to 41h is substantially a sinusoidal wave but, without being limited thereto, it may, e.g., be substantially square wave. The power supply portion 6 is made up of a first CPU circuit 61; an input portion 62 which receives an input of commercial AC voltage (three-phase AC 200V or 400V); and six diodes 63 which rectify the inputted AC voltage and once convert the AC voltage to DC voltage, so that DC voltage can be outputted to the oscillation portion 7 through DC voltage lines 64a, 64b. Between the DC voltage lines 64a, 64b there is disposed a switching transistor 65 so that, by means of a driver circuit 66 which is connected to the first CPU circuit 61, the on-off switching of the switching transistor 65 can be controlled.

On the other hand, the oscillation portion 7 is made up of a second CPU circuit 71 which is connected to the first CPU circuit 61 in a manner to be communicated freely; first to fourth switching transistors 72a to 72d which constitute an oscillating switching circuit 72 disposed between the DC voltage lines 64a, 64b; and another driver circuit 73 which is connected to the second CPU circuit 71 so as to be freely communicated to control the on-off switching of each of the switching transistors 72a to 72d. Now, by means of the driver circuit 66 which receives an output signal from the first CPU circuit 61, the switching transistor 65 is switched on. Then, the DC voltage is outputted to the oscillation portion 7 through the DC voltage lines 64a, 64b. Then, by means of the driver circuit 73 which received the output signal from the second CPU circuit 71, each of the switching transistors 72a to 72d is controlled so that the on-off switching timing can be reversed between the first and fourth switching transistors 72a, 72d and the second and third switching transistors 72b, 72c. Then, AC voltage of sinusoidal wave of a constant voltage is outputted from the oscillation switching circuit 72 to the pair of targets 41a, 41b through the AC voltage lines 75a, 75b via the transformer 74. The first CPU circuits 61 of each of the AC power sources E1 to E4 are connected in a manner to be communicated to one another and, therefore, each of the AC power sources E1 to E4 can be synchronously driven by the output signal of any one of the CPU circuits 61.

In case a transparent conductive film is formed on the surface of the to-be-processed substrate S, the to-be-processed substrate S is transported to a position lying opposite to each of the targets 41a to 41h by means of the substrate transporting means 2. Once the sputtering chamber 12 has reached a predetermined vacuum pressure, a predetermined sputtering gas (and a reactant gas) is introduced through the gas introducing means 3. Then, by operating the AC power sources E1 to E4, AC voltage is applied to each pair of the targets 41a to 41h. Each of the targets 41a to 41h is alternately switched to anode electrode and cathode electrode. Glow discharge is caused to be generated between the anode electrode and the cathode electrode to thereby form a plasma atmosphere. According to this arrangement, the ions in the plasma atmosphere are accelerated toward, and impinged on, one side of the targets 41a to 41h that has become cathode electrode. As a result of splashing of the sputtered particles, a transparent conductive film can be formed on the surface of the to-be-processed substrate S.

By arranging the sputtering apparatus 1 as described above, even in case the targets 41a to 41h are oxide targets of indium and tin, the electric charges in charge-up that remain at the surface of the targets 41a to 41h will be cancelled when voltage of the opposite phase is applied. As a result, the occurrence of abnormal discharging attributable to the charge-up in the targets 41a to 41h can be prevented. On the other hand, the surface of the to-be-processed substrate S in a floating state is also charged up. In case there is used, in the step of manufacturing FED, a substrate in which especially a metal film to constitute an electrode or an insulating film has been formed, electric charges in charge-up will be likely to stay on the insulating film. Therefore, it is necessary to arrange that abnormal discharging due to charge-up does not occur due to charge-up of the to-be-processed substrate S.

In the embodiment of this invention, an arrangement was made: that, as shown in FIG. 3, during sputtering each of the switching transistors 65 of each of the AC current power sources E1 to E4 was switched off only for a predetermined period of time by the output signal from a single CPU circuit 61 at predetermined intervals from the start of sputtering; and that the electric power application from each of the AC power supply sources E1 to E4 to all of the targets 41a to 41h was intermittently stopped at the same time. It is to be noted here that this simultaneous intermittent stopping means a state in which the power application to all of the targets 41a to 41h is stopped for a predetermined period of time. It does not mean that the timing of stopping the power application or the timing of starting of power application again by switching on or off of each of the switching transistors 65 coincides with each other (in other words, the timing of stopping the power application or the timing of starting once again of the power application may disagree with one another among each of the AC power sources E1 to E4).

According to this arrangement, even if the to-be-processed substrate S is charged up during sputtering as a result of supply of the electrons ionized in front of the targets 41a to 41h, or of the secondary electrons generated by sputtering, the retention of the electric charges in the charge-up at the surface of the to-be-processed substrate S will be remarkably restrained, in a state in which the periodical power application to all of the targets 41a to 41h is stopped. This is due to the combined effect in: that the plasma in front of the targets 41a to 41h will once disappear whereby there are neither ionized electrons nor secondary electrons toward the to-be-processed substrate S; and that the electric charges in charge-up at the surface of the to-be-processed substrate S will disappear as a result of neutralization by the sputtered particles and ionized sputtering gas ions. As a result, the abnormal discharging accompanied by charge-up of the to-be-processed substrate S will be prevented from occurring, whereby the transparent conductive film can be formed well. By commonly using the switching transistor 65, which switches the power application to the targets 41a to 41h or stopping thereof, as a switching element for intermittently stopping the power application to the targets 41a to 41h, the intermittent stopping of the power application to the targets 41a to 41h can be materialized by a simple constitution without adding a separate part.

The time or frequency of stopping the power application (the number of times of stopping during sputtering) is adequately set depending on the target species or the kind of to-be-processed substrate S such that the sum of the time of intermittent stopping falls within a range of 10% of the sputtering time. If the sum of the time of intermittent stopping exceeds 10% of the sputtering time, the sputtering time becomes longer and the productivity becomes poor. For example, in the step of manufacturing FED, in case oxides of indium and tin are used as the targets 41a to 41h, and a transparent conductive film of ITO is formed to a thickness of 720 Å on the surface of the to-be-processed substrate S on which a metallic film to constitute electrode or an insulating film has been formed, the above-described total time may be set within a range of 1.0˜5.0 ms.

By the way, when ITO film is formed by reactive sputtering by using, as the targets 41a to 41h, an oxide target of indium and tin or an alloy target of indium and tin, and by using, as a reactant gas, an H₂O gas or a mixed gas of an H₂O gas and an O₂ gas, there will locally occur micro-crystallized portion on the ITO film that was formed on the surface of the to-be-processed substrate if the H₂O gas that was introduced into the sputtering chamber 12 is locally consumed. If the micro-crystallization portion locally occurs to the ITO film, not only is the conductivity lowered, but also becomes non-uniform the etching rate per unit time on the plane of the to-be-processed substrate when the ITO film is etched in the subsequent step, whereby the productivity becomes poor.

On the other hand, by intermittently stopping the power application to each of the targets 41a to 41h as in this invention, at the time of stopping the power application, the H₂O gas that was introduced into the sputtering chamber 12 will be supplied over the entire surface of the to-be-processed substrate S. As a result, the transparent conductive film can be prevented from getting locally micro-crystallized, whereby an amorphous transparent conductive film can be obtained in a more stable manner. Further, in case the ITO film is etched in the subsequent step, the etching rate per unit time can be made substantially uniform on the plane of the to-be-processed substrate.

In the embodiment of this invention, a description was made of an example in which eight targets were used and AC power source was applied to the respectively adjoining targets. However, without being limited to the above example, the number of targets, and the combination of the targets can be appropriately set depending on the process for forming a transparent conductive film. In addition, a description was also made of an example in which the power application to each of the targets 41a to 41h is intermittently stopped at the same time. However, as long as the abnormal discharging as a result of charge-up of the to-be-processed substrate S can be prevented, it is not necessary to stick to the above example. For example, as shown in FIG. 4, out of the eight targets disposed in a side-by-side relationship, the adjoining four targets may be made to be a target group to thereby perform the following control, i.e., in a state in which the power application to one target group 41a to 41d is stopped, the power application to the other target group 41e to 41h is continued. After the power application to the one target group 41a to 41d has been resumed, the power application to the other target group 41e to 41h is stopped. According to this arrangement, the retention of the electric charges in charge-up can be controlled.

### BRIEF DESCRIPTION OF THE DRAWINGS

FIG. 1 is a schematic view of a sputtering apparatus of this invention;

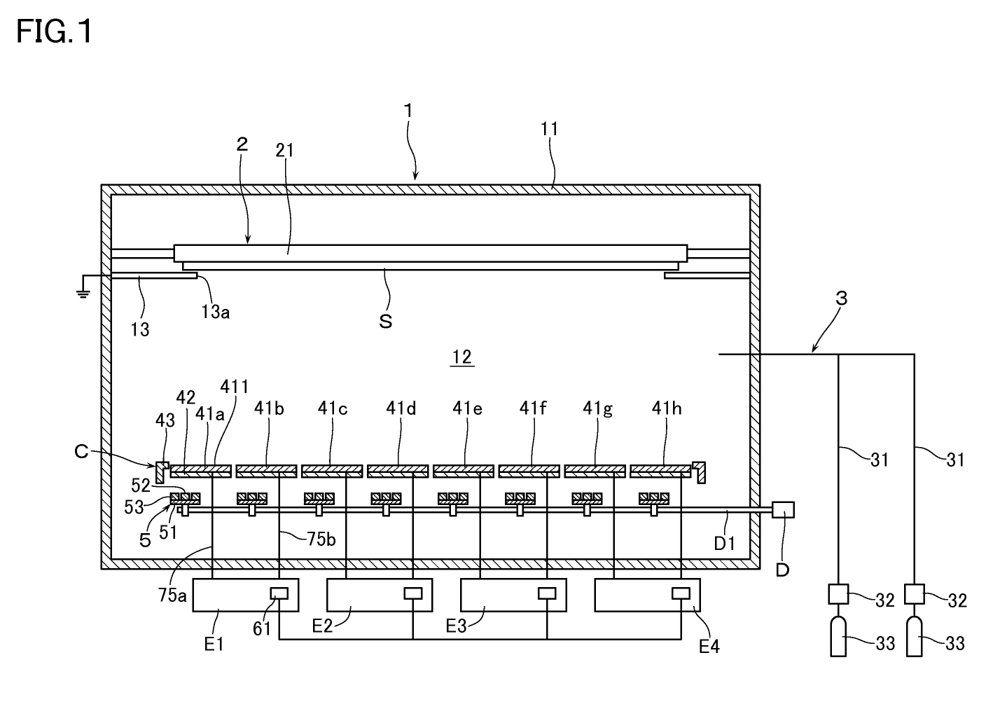

FIG. 2 is a diagram showing an AC power source of the sputtering apparatus as shown in FIG, 1,

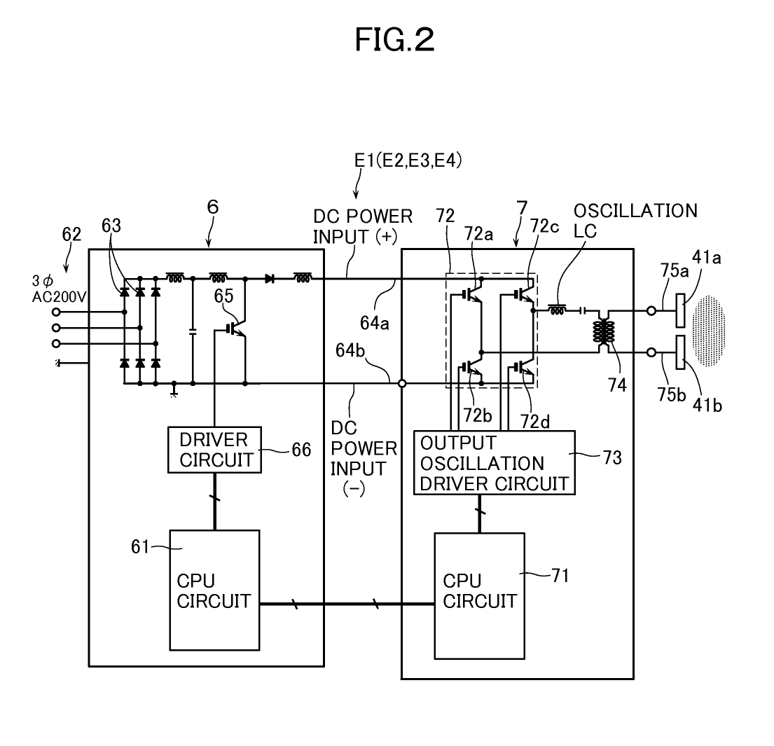

FIG. 3 is a diagram showing the control of power application from the AC power sources to the targets;

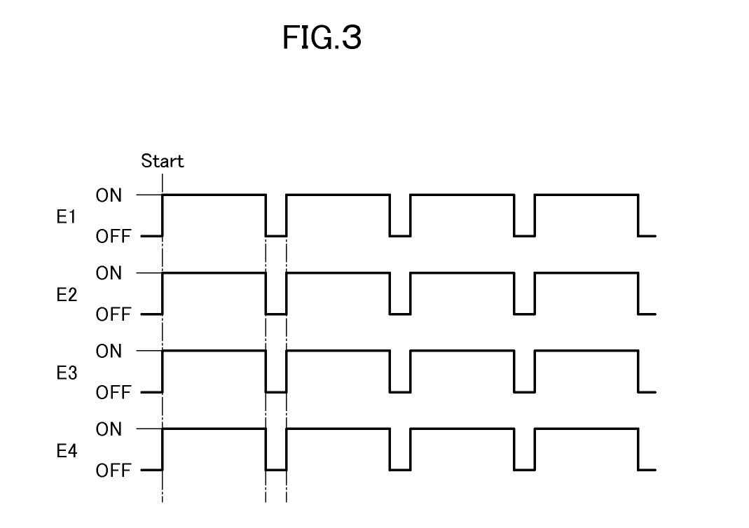

FIGS. 4(a) to 4(c) are other illustrations to explain another control of power application from the AC power sources to the targets.

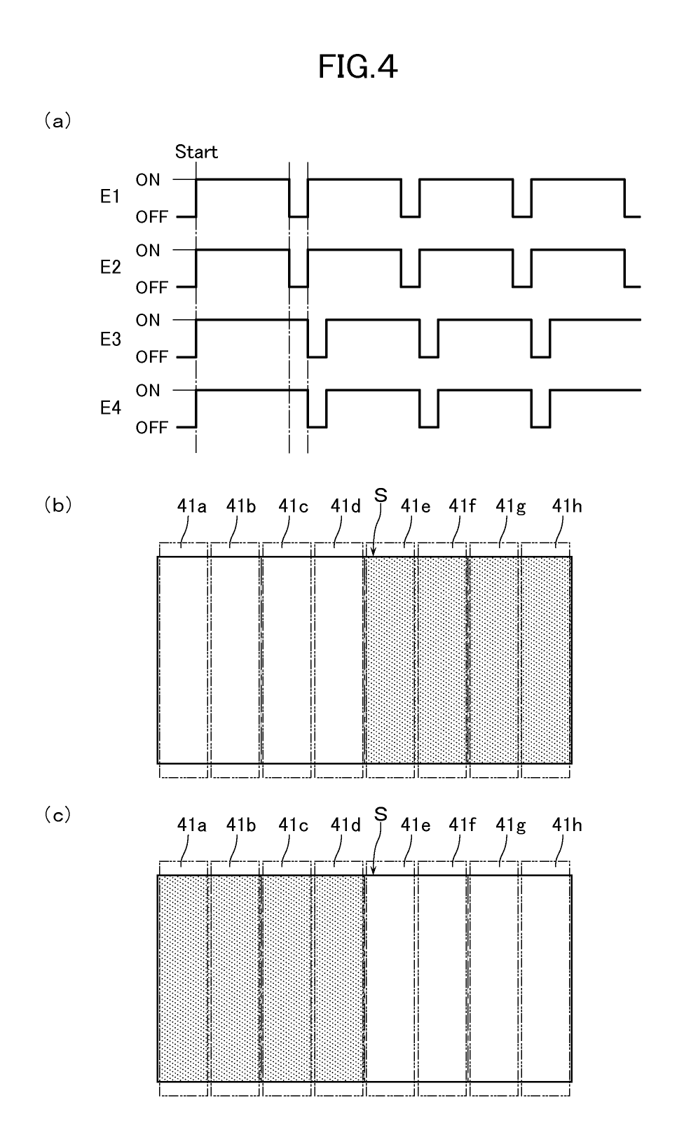

### DESCRIPTION OF REFERENCE NUMERALS AND CHARACTERS

1 sputtering apparatus

12 sputtering chamber

3 gas introducing means

41a to 41h targets

E1 to E4 AC power sources

65 switching element

S substrate to be processed (to-be-processed substrate)

1. A sputtering method of forming a predetermined transparent conductive film on a surface of a substrate to be processed, the method comprising:
introducing a process gas into a sputtering chamber;
applying electric power to respective pairs of targets by alternately changing polarity at a predetermined frequency, the pairs of targets being formed out of a plurality of targets disposed side by side with, and at a predetermined distance to, one another in a manner to lie opposite to the substrate to be processed inside the sputtering chamber;
alternately switching each of the targets to an anode electrode and a cathode electrode to generate glow discharge between the anode electrode and the cathode electrode such that a plasma atmosphere is formed to sputter each of the targets,
wherein, during sputtering, application of electric power to each of the targets is intermittently stopped.

2. The sputtering method according to claim 1, wherein the intermittent stopping is performed at a constant cycle with respect to all of the targets disposed side by side with one another.

3. The sputtering method according to claim 1, wherein a sum of the time of intermittent stopping is set to a range below 10% of a sputtering time required to form a predetermined transparent conductive film in a constant thickness on the surface of the substrate to be processed.

4. The sputtering method according to claim 1, wherein as the target, an oxide target of indium and tin or an alloy target of indium and tin is used, and wherein the process gas to be introduced into the processing chamber includes an H₂O gas.

5. A sputtering apparatus comprising:
a sputtering chamber containing therein a plurality of oxide targets of indium and tin or alloy targets of indium and tin, the targets being disposed in the sputtering chamber side by side with, and at a predetermined distance to, one another in a manner to lie opposite to a substrate to be processed;
AC power sources enabling to apply electric power to the targets that respectively make a pair, by alternately changing polarity at a predetermined frequency;
a gas introducing means enabling to introduce a process gas into the sputtering chamber,
wherein each of the AC power sources has: a switching element for switching between application and stopping of electric power to respective pairs of targets; and a control means for controlling the switching of the switching element such that the power application to the targets is intermittently stopped during sputtering.

6. The sputtering method according to claim 2, wherein a sum of the time of intermittent stopping is set to a range below 10% of a sputtering time required to form a predetermined transparent conductive film in a constant thickness on the surface of the substrate to be processed.

7. The sputtering method according to claim 2, wherein as the target, an oxide target of indium and tin or an alloy target of indium and tin is used, and wherein the process gas to be introduced into the processing chamber includes an H₂O gas.

8. The sputtering method according to claim 3, wherein as the target, an oxide target of indium and tin or an alloy target of indium and tin is used, and wherein the process gas to be introduced into the processing chamber includes an H₂O gas.
